(19) United States
(12) Patent Application Publication
(10) Pub. No.: US 2024/0164078 A1
(43) Pub. Date: May 16, 2024

(54) SHIELDING FOIL AND COMMUNICATION CABLE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Hiroyuki KOBAYASHI, Mie (JP)

(21) Appl. No.: 18/284,208

(22) PCT Filed: Mar. 17, 2022
(86) PCT No.: PCT/JP2022/012303

§ 371 Date: Sep. 26, 2023

(30) Foreign Application Priority Data
Mar. 31, 2021 (JP) 2021-059079

(51) Int. Cl. H05K 9/00; H01B 11/18; H01B 13/22

(52) U.S. Cl. CPC H05K 9/0098; H01B 11/1813; H01B 13/225

(57) ABSTRACT

A shielding foil 10 includes a metal foil 12 with a thickness of 5 μm or more and 12 μm or less made of a non-magnetic metal, and a magnetic layer 13 with a thickness of 0.05 μm or more and 6 μm or less made of an oxide magnetic substance, the metal foil 12 and the magnetic layer 13 being integrally laminated. A communication cable includes a conductor, an insulating layer covering the outer circumference of the conductor, and the shielding foil 10 that surrounds the outside of the insulating layer.

### TECHNICAL FIELD

The present disclosure relates to a shielding foil and communication cable.

### BACKGROUND

In communication cables used in the automobile field and the like, a metal foil made of copper, aluminum, an alloy containing copper or aluminum, or the like may be disposed on the outer circumference of a core wire to serve as a noise shielding layer for reducing the entrance of noise from the outside and the emission of noise to the outside. For example, Patent Document 1 discloses a shielded electric wire provided with a metal-foil shield. Moreover, a sheath layer in which powder of a magnetic material such as ferrite is dispersed in an organic polymer may be provided in place of a metal foil or together with a metal foil as another form of a noise shielding layer. For example, Patent Document 2 discloses a cable having such a sheath layer.

### PRIOR ART DOCUMENT

### Patent Document

Patent Document 1: JP 2009-146850 A
Patent Document 2: JP H11-086641 A

### SUMMARY OF THE INVENTION

### Problems to be Solved

When a material in which powder of a magnetic material is dispersed in an organic polymer is used in a communication cable or the like for the purpose of noise shielding, the particles of the powder of the magnetic material are inevitably spaced apart from one another at intervals. The noise shielding ability cannot be effectively improved due to an electromagnetic wave passing through these intervals. Although it is also conceivable that the noise shielding properties can be improved by using a sheath layer in which powder of a magnetic material is dispersed in an organic polymer, in a state of being laminated on a layer constituted by a metal foil or a metal braid, a gap is likely to be formed between the laminated layers. Such a gap between the layers also inhibits an improvement in the noise shielding ability.

In light of the description above, it is an object of the present invention to provide a noise shielding member in which a decrease in the noise shielding ability due to an influence of a gap is suppressed, and a communication cable provided with such a noise shielding member.

### Means to Solve the Problem

A shielding foil according to the present disclosure includes: a metal foil with a thickness of 5 μm or more and 12 μm or less made of a non-magnetic metal; and a magnetic layer with a thickness of 0.05 μm or more and 6 μm or less made of an oxide magnetic substance, the metal foil and the magnetic layer being integrally laminated.

A communication cable according to the present disclosure includes: a conductor; an insulating layer covering an outer circumference of the conductor; and the above-mentioned shielding foil that surrounds an outside of the insulating layer.

### Effect of the Invention

The shielding foil according to the present disclosure is a noise shielding member in which a decrease in the noise shielding ability due to an influence of a gap is suppressed, and the communication cable according to the present disclosure is a communication cable provided with such a noise shielding member.

### BRIEF DESCRIPTION OF THE DRAWINGS

FIGS. 1A to 1C are cross-sectional views each showing a layer configuration of a shielding foil according to an embodiment of the present disclosure, and show different aspects.

FIG. 2 is a cross-sectional view showing the configuration of a communication cable according to an embodiment of the present disclosure.

### DETAILED DESCRIPTION TO EXECUTE THE INVENTION

### Description of Embodiments of the Present Disclosure

First, aspects of the present disclosure will be described.

A shielding foil according to the present disclosure includes: a metal foil with a thickness of 5 μm or more and 12 μm or less made of a non-magnetic metal; and a magnetic layer with a thickness of 0.05 μm or more and 6 μm or less made of an oxide magnetic substance, the metal foil and the magnetic layer being integrally laminated.

The shielding foil is formed by integrally laminating the metal foil and the magnetic layer. In this shielding foil, both the metal foil and the magnetic layer contribute to noise shielding, and therefore, the entire shielding foil exhibits a high noise shielding ability. In particular, intervals resulting in breaking of the continuity of the magnetic material inside the magnetic layer are less likely to be formed due to the magnetic material in the magnetic layer being in the form of a continuous layer rather than the form of a powder. Also, since the magnetic layer is integrally formed with the metal foil, a gap is also less likely to be formed between the magnetic layer and the metal foil. As described above, since the intervals and the gap through which an electromagnetic wave passes are less likely to be formed inside the magnetic layer and between the magnetic layer and the metal foil, respectively, the shielding foil exhibits high noise shielding properties. Furthermore, due to the metal foil and the magnetic layer having thicknesses greater than or equal to the lower limits above, a particularly high noise shielding ability is ensured. Meanwhile, due to the thicknesses of the metal foil and the magnetic layer being reduced to be smaller than or equal to the upper limits above, the shielding foil has high flex resistance, and can maintain a high noise shielding ability even after being bent. Also, the shielding foil can be easily installed through winding or the like, and a member that includes the shielding foil, such as a communication cable, can be manufactured with high productivity.

Here, it is preferable that the metal foil is made of copper or a copper alloy, and the magnetic layer is made of ferrite. With this configuration, the shielding foil exhibits high noise shielding properties. Also, the shielding foil can be formed using general-purpose materials.

It is preferable that the shielding foil further includes a substrate with a sheet shape containing an organic polymer, wherein the metal foil and the magnetic layer are formed on a surface of the substrate. With this configuration, a shielding foil having a metal foil and a magnetic layer that each have an appropriate thickness and few defects such as cracks can be simply manufactured. Also, the handleability of the shielding foil is improved.

A communication cable according to the present disclosure includes: a conductor; an insulating layer covering an outer circumference of the conductor; and the above-mentioned shielding foil that surrounds an outside of the insulating layer. As described above, the shielding foil according to the present disclosure includes a metal foil and a magnetic layer that are integrated with each other, and the intervals and the gap are less likely to be formed inside the magnetic layer and between the magnetic layer and the metal foil, respectively. Therefore, due to the shielding foil being disposed on the outer circumference of a core wire constituted by the conductor and the insulating layer in the communication cable, the entrance of an electromagnetic wave to the core wire and the emission of an electromagnetic wave from the core wire are effectively suppressed, and thus a high noise shielding ability is exhibited. Furthermore, due to the thicknesses of the metal foil and the magnetic layer included in the shielding foil being set to be within predetermined ranges, high noise shielding properties are imparted to the communication cable, and the high noise shielding properties can be maintained even after the communication cable is bent. Also, the communication cable can also be manufactured with high productivity through a process that includes a step of disposing the shielding foil on the outer circumference of the core wire.

Here, it is preferable that the communication cable further includes a sheath layer that covers an outside of the insulating layer and contains an organic polymer and a powdery magnetic material. With this configuration, in addition to the shielding foil, the sheath layer imparts higher noise shielding properties to the communication cable. The sheath layer also serves to protect internal constituent components such as the shielding foil from contact with external objects, etc.

Also, it is preferable that the communication cable further includes a metal braid on an outside or an inside of the shielding foil. With this configuration, higher noise shielding properties are imparted to the communication cable due to the communication cable having the metal braid in addition to the shielding foil.

It is preferable that the communication cable is formed as a coaxial cable. Although a coaxial cable is susceptible to the influence of noise due to its structure, the communication cable has high noise resistance due to the shielding foil being provided on the outer circumference of the core wire.

### Details of Embodiments of the Present Disclosure

Hereinafter, a shielding foil and a communication cable according to embodiments of the present disclosure will be described in detail with reference to the drawings. The communication cable according to an embodiment of the present disclosure includes the shielding foil according to an embodiment of the present disclosure serving as a noise shielding member.

(Shielding Foil)

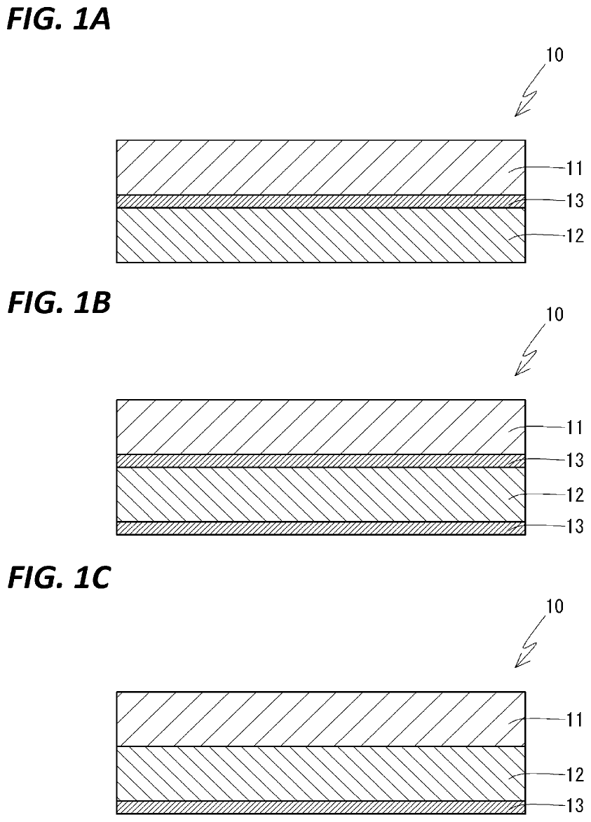

First, a shielding foil according to an embodiment of the present disclosure will be described. FIGS. 1A to 1C are cross-sectional views each showing a layer configuration of a shielding foil 10 according to an embodiment of the present disclosure. FIGS. 1A to 1C show different aspects.

The shielding foil 10 according to this embodiment has a structure in which a substrate 11, a metal foil 12, and a magnetic layer 13 are integrally laminated. That is to say, at least one layer of the substrate 11, at least one layer of the metal foil 12, and at least one layer of the magnetic layer 13 are joined to each other in a state in which they cannot be easily separated, and thus a complex is formed. There is no particular limitation on the lamination order of the layers and the number of layers. In the aspect shown in FIG. 1A, the magnetic layer 13 and the metal foil 12 are laminated on one surface of the substrate 11 in this order. In the aspect shown in FIG. 1B, the magnetic layer 13, the metal foil 12, and the magnetic layer 13 are laminated on one surface of the substrate 11 in this order. That is to say, the magnetic layers 13 are in contact with the surfaces on two sides of the metal foil 12, and the total number thereof is two. In the aspect shown in FIG. 1C, the metal foil 12 and the magnetic layer 13 are laminated on one surface of the substrate 11 in this order. Although the metal foil 12 and the magnetic layer 13 may be formed on one surface and the other surface of the substrate 11, respectively, and be separated from each other, it is preferable that the magnetic layer 13 is formed so as to be in contact with a surface of the metal foil 12 as shown in FIGS. 1A to 1C. Out of the laminate structures shown in FIGS. 1A to 1C, the one shown in FIG. 1A is most preferable from the viewpoint of electrical continuity with an adjacent conductive member such as a braid layer 5 of the communication cable 1, which will be described later.

The substrate 11 is a member with a sheet shape and is made of an organic polymer material. Although the substrate 11 is not necessarily provided in the shielding foil 10, using the substrate 11 makes it possible to simply form the metal foil 12 and the magnetic layer 13 that each have an appropriate thickness and few defects. Also, the mechanical strength and the handleability of the shielding foil 10 can be improved. Although there is no particular limitation on the organic polymer included in the substrate 11, examples thereof include polyethylene terephthalate (PET), polyolefins such as polypropylene (PP), and polyvinyl chloride (PVC). In particular, PET can be favorably used from the viewpoint of high mechanical strength, etc. The substrate 11 may contain various additives as appropriate in addition to the organic polymer. Although there is no particular limitation on the thickness of the substrate 11 as well, the thickness thereof is preferably 2 μm or more from the viewpoint of enhancing the effects of improving the mechanical strength and the handleability of the shielding foil 10, etc. Meanwhile, the thickness of the substrate 11 is preferably 20 μm or less from the viewpoint of securing flexibility.

The metal foil 12 is a layer made of a non-magnetic metal. The metal foil 12 serves to shield electromagnetic noise. Although there is no particular limitation on the metal included in the metal foil 12, copper, a copper alloy, aluminum, an aluminum alloy, silver, and a silver alloy, which are widely used for noise shielding, and materials obtained by plating the surfaces of these metals with Sn, Ni, Ag, Au, or the like can also be favorably used in this embodiment. In particular, it is preferable to use copper or a copper alloy. Note that non-magnetic metal refers to a metal having no ferromagnetism, and particularly to a paramagnetic metal.

The thickness of the metal foil 12 is 5 μm or more and 12 μm or less. Due to the thickness of the metal foil 12 being 5 μm or more, the noise shielding ability exhibited by the metal foil 12 is sufficiently obtained. Also, sufficient mechanical strength is achieved. The thickness of the metal foil 12 is more preferably 8 μm or more from the viewpoint of further improving these properties. Meanwhile, due to the thickness of the metal foil 12 being 12 μm or less, the flex resistance of the metal foil 12 is increased. That is to say, the metal foil 12 is less likely to be damaged (e.g., cracked) even when the shielding foil 10 is repeatedly bent. As a result, it is possible to suppress a decrease in the noise shielding properties caused by an electromagnetic wave passing through a damaged portion (e.g., a crack). Also, the shielding foil 10 is highly flexible due to the metal foil 12 not being too thick, and a step of disposing the shielding foil 10 on a predetermined portion by, for example, winding the shielding foil 10 around the outer circumference of a core wire 4 of the communication cable 1, which will be described later, can be easily performed, thus making it possible to improve the productivity of a member or an apparatus that includes the shielding foil 10. The thickness of the metal foil 12 is more preferably 10 μm or less from the viewpoint of further improving these effects.

The magnetic layer 13 is a layer made of an oxide magnetic substance. The oxide magnetic substance refers to a ferromagnetic substance composed of a metal oxide. A metal oxide with soft magnetism is preferable. The magnetic layer 13 absorbs an electromagnetic wave due to magnetic loss, and thus exhibits an effect of attenuating electromagnetic noise. Although there is no particular limitation on the specific type of metal oxide included in the magnetic layer 13, ferrite can be favorably used. In particular, Ni—Zn ferrite, Mn—Zn ferrite, and Sr ferrite can be favorably used. Using an oxide magnetic substance for the magnetic layer 13 rather than a metal magnetic substance improves the chemical stability, thus making it possible to form the magnetic layer 13 as a thin film and stably maintain physical properties such as soft magnetism of the magnetic layer 13 even after long-term use. Examples of oxide magnetic substances that can be used to form the magnetic layer 13 instead of ferrite include chromium oxide and manganese oxide. The magnetic layer 13 may contain other types of substances such as a non-ferromagnetic metal oxide, an organic compound, a metal, a metal compound other than an oxide in addition to a ferromagnetic metal oxide to the extent that they can be considered as impurities.

The thickness of the magnetic layer 13 is 0.05 μm or more and 6 μm or more. Due to the thickness of the magnetic layer 13 being 0.05 μm or more, the noise shielding effect exhibited by the magnetic layer 13 is sufficiently achieved. Even if defects occur locally in the magnetic layer 13 during manufacturing steps and the like, when the average thickness of the entire magnetic layer 13 is 0.05 μm or more, defects are less likely to penetrate the magnetic layer 13 in the thickness direction as cracks or holes do, thus making it possible to suppress a noise shielding failure caused by an electromagnetic wave passing through the penetrated portions. The thickness of the magnetic layer 13 is more preferably 0.1 μm or more and even more preferably 0.5 μm or more from the viewpoint of further improving the noise shielding properties exhibited by the magnetic layer 13. Meanwhile, due to the thickness of the magnetic layer 13 being reduced to be smaller than or equal to 6 μm, the magnetic layer 13 has high flex resistance, and thus the magnetic layer 13 is less likely to be damaged (e.g., cracked) even when the shielding foil 10 is repeatedly bent. Thus, a decrease in the noise shielding ability caused by an electromagnetic wave passing through a damaged portion (e.g., crack) is less likely to occur. Also, the shielding foil 10 is highly flexible due to the magnetic layer 13 not being too thick, and the productivity of a member or an apparatus that includes the shielding foil 10 can be improved.

In the shielding foil 10 according to this embodiment, a magnetic substance is not dispersed in the form of a powder but forms a layer. That is to say, the magnetic substance forms a continuous structure. When the magnetic substance is in the form of a powder, which is discontinuous, the particles of the powder are inevitably spaced apart from one another at intervals, and there is a possibility that noise will not be sufficiently shielded due to an electromagnetic wave passing through the intervals. However, in this embodiment, due to the magnetic substance forming a continuous layer, intervals through which an electromagnetic wave can pass are less likely to be formed unlike the powdery material. Accordingly, the shielding foil 10 exhibits high noise shielding properties.

In the shielding foil 10 according to this embodiment, layers made of two types of materials, namely a non-magnetic metal and an oxide magnetic substance, which shield electromagnetic noise through different mechanisms, are laminated, and thus a high noise shielding ability is achieved. In particular, the metal foil 12 made of a non-magnetic metal and the magnetic layer 13 made of an oxide magnetic substance are integrally joined to each other, and thus a gap is less likely to be formed between the layers. A gap between the layers also causes a decrease in the noise shielding properties due to an electromagnetic wave passing therethrough as in the case of the above-described intervals between the particles of the magnetic substance, but in the shielding foil 10 according to this embodiment, intervals are less likely to be formed in the magnetic layer 13 while a gap is less likely to be formed at an interface between the magnetic layer 13 and the metal foil 12 as well, and thus high noise shielding properties are achieved. Furthermore, in the shielding foil 10 according to this embodiment, due to the thicknesses of the metal foil 12 and the magnetic layer 13 being within the predetermined ranges above, high noise shielding properties are achieved, high flex resistance is achieved, and the productivity of a member or an apparatus that includes the shielding foil 10 is improved.

There is no particular limitation on a method for integrally joining the metal foil 12 and the magnetic layer 13 in the shielding foil 10 according to this embodiment, and a method for integrally joining these layers 12 and 13 and the substrate 11 in the shielding foil 10. An aspect in which the metal foil 12 and the magnetic layer 13 are formed on a surface of the substrate 11 through vapor deposition, plating, bonding, or the like in a predetermined lamination order can be given as an example. The magnetic layer 13 can be particularly favorably formed using a vapor-deposition technique. For example, it is sufficient that a layer made of a metal that produces a ferromagnetic metal oxide through oxidation is formed through vapor deposition. Then, it is sufficient that, during or after the vapor deposition, the metal layer is brought into contact with an oxygen-containing gas such as air and is thus oxidized to produce a metal oxide. The vapor deposition can be carried out using a film formation method employing a common vacuum apparatus.

Although there is no particular limitation on the application of the shielding foil 10 according to this embodiment, the noise shielding properties can be imparted to various members and apparatuses by providing the shielding foil 10 to the members and apparatuses through winding, attaching, or the like. That is to say, it is possible to suppress a phenomenon in which noise is generated in the members and the like due to the entrance of an external electromagnetic wave into the members and the like, and a phenomenon in which the members and the like serve as a noise source with respect to the outside due to the emission of an electromagnetic wave from the members and the like. A favorable example of a member to which the shielding foil 10 is provided is a communication cable, which will be described next.

(Communication Cable)

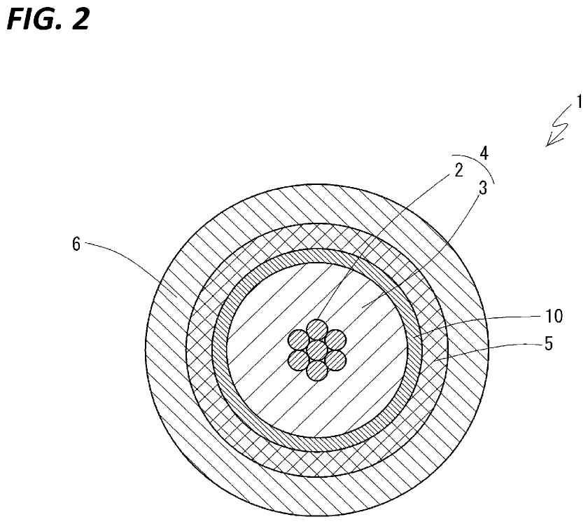

Hereinafter, a communication cable according to an embodiment of the present disclosure will be described. FIG. 2 shows a cross-sectional view of a communication cable 1 according to an embodiment of the present disclosure taken in a direction perpendicular to the axial direction.

The communication cable 1 according to this embodiment is formed as a coaxial cable. Specifically, the communication cable 1 includes a core wire 4 that includes: a conductor 2; and an insulating layer 3 covering the outer circumference of the conductor 2. The above-described shielding foil 10 according to this embodiment and a braid layer 5 are provided, as noise shielding members, on the outer circumference of the core wire 4 in this order from the inside. A sheath layer 6 that also functions as a noise shielding member is provided on the outer circumference of the braid layer 5.

The communication cable 1 as described above, which is formed as a coaxial cable that includes a noise shielding member such as the shielding foil 10 on the outer circumference of the core wire 4, can be favorably used to transmit a signal in a high-frequency range greater than or equal to 1 GHz. However, as long as at least the shielding foil 10 is provided to cover the outside of the core wire 4, the structure of the communication cable 1 according to the present disclosure is not limited to the structure as described above, and it is sufficient that a configuration according to the communication frequency or the application is employed. For example, although a single insulated wire is used as the core wire 4 in the aspect above, a plurality of insulated wires may be used. Specifically, the core wire 4 can be configured such that a pair of insulated wires are twisted together or arranged side by side so as to transmit differential signals.

The braid layer 5 and the sheath layer 6 enhance the noise shielding properties of the communication cable 1, but these members are not necessarily provided. Even when only the shielding foil 10 is provided as a noise shielding member in the communication cable 1, high noise shielding properties are achieved, and therefore, in the case where noise does not have a significant influence, etc., the braid layer 5 and/or the sheath layer 6 need not be provided. Although each of the described layers is formed so as to be in direct contact with the outer circumference of the adjacent inner constituent layer in the above-described aspect, the communication cable 1 may include a constituent layer other than the above-described layers as appropriate.

The core wire 4 is a signal wire through which an electric signal is transmitted in the communication cable 1, and includes: the conductor 2; and the insulating layer 3 covering the outer circumference of the conductor 2. There is no particular limitation on the materials for forming the conductor 2 and the insulating layer 3. Although various metal materials can be used as the materials for forming the conductor 2, it is preferable to use copper or a copper alloy from the viewpoint of their high conductivity. Although the conductor 2 may be constituted by a solid wire, it is preferable that the conductor 2 is constituted by a twisted wire formed by twisting a plurality of (e.g., seven) strands together from the viewpoint of improving the flexural flexibility, etc. The insulating layer 3 insulates the conductor 2 in the core wire 4, and contains an organic polymer. There is no particular limitation on the type of organic polymer, and examples thereof include olefin-based polymers such as polyolefins and olefin-based copolymers, halogen-based polymers such as polyvinyl chloride, various engineering plastics, elastomers, and rubbers. The insulating layer 3 may contain additives as appropriate in addition to the organic polymer.

The shielding foil 10 according to an embodiment of the present disclosure is disposed so as to surround the outer circumference of the core wire 4 and functions as a noise shielding member. That is to say, the shielding foil 10 suppresses a phenomenon in which noise occurs in a signal transmitted through the core wire 4 due to the entrance of an external electromagnetic wave into the core wire 4, and a phenomenon in which the core wire 4 serves as a noise source due to the emission of an electromagnetic wave generated by a signal transmitted through the core wire 4, to the outside. Although there is no limitation on the front-to-back direction when the shielding foil 10 is disposed on the outer circumference of the core wire 4, it is preferable that the surface of the substrate 11 is located on a side opposite to the braid layer 5 from the viewpoint of electrically connecting the braid layer 5 and the metal foil 12 when the metal foil 12 and the magnetic layer 13 are provided on one surface of the substrate 11 as shown in FIGS. 1A to 1C. Although the shielding foil 10 may be disposed in a longitudinally lapped manner or a laterally wound manner, it is preferable to dispose the shielding foil 10 in a longitudinally lapped manner from the viewpoint of improving the noise shielding properties.

The braid layer 5 is formed as a braid obtained by braiding a plurality of metal strands together into a hollow tube. Examples of the metal strands used in the braid layer 5 include those made of metal materials such as copper, a copper alloy, aluminum, and an aluminum alloy, or those obtained by plating the surfaces of metal strands made of the metal materials with tin or the like. Although the braid layer 5 is not necessarily provided in the communication cable 1 as described above, when provided, the braid layer 5 exhibits noise shielding properties due to electrostatic shielding along with the metal foil 12 of the shielding foil 10. Although the braid layer 5 may be provided on the outside or the inside of the shielding foil 10, it is preferable to provide the braid layer 5 on the outside of the shielding foil 10 from the viewpoint of reducing signal loss, etc.

The sheath layer 6 contains a powdery magnetic material and an organic polymer component, and serves to protect members disposed on the inside of the sheath layer 6 from contact with an external object, etc., and to improve the noise shielding ability of the communication cable 1. In the sheath layer 6, the powder of the magnetic material is dispersed in a matrix made of the organic polymer component. The magnetic material contained in the sheath layer 6 is preferably a ferromagnetic material, and more preferably a metal or metal oxide with soft magnetism. When the powdery magnetic material contained in the sheath layer 6 is made of a metal oxide, the metal oxide may be the same as or different from the metal oxide included in the magnetic layer 13 of the shielding foil 10. There is no particular limitation on the type of organic polymer included in the sheath layer 6, and examples thereof include olefin-based polymers such as polyolefins and olefin-based copolymers, halogen-based polymers such as polyvinyl chloride, various engineering plastics, elastomers, and rubbers. The sheath layer 6 is not necessarily provided in the communication cable 1 as described above, and when provided, the sheath layer 6 may be free from a magnetic material. However, when the sheath layer 6 containing a magnetic material is provided, the sheath layer 6 exhibits noise shielding properties due to magnetic loss together with the magnetic layer 13 in the shielding foil 10. Also, as the sheath layer 6, a layer free from a magnetic material may be further provided on the outer circumference of a layer containing a magnetic material. In this case, the layer free from a magnetic material protects the layer containing a magnetic material.

The communication cable 1 according to this embodiment includes the above-described shielding foil 10, and thus has high noise shielding properties. The reason for this is that, since the shielding foil 10 includes the metal foil 12 and the magnetic layer 13 that are integrated with each other, and intervals and a gap are less likely to be formed inside the magnetic layer 13 and between the magnetic layer 13 and the metal foil 12, respectively, a decrease in the noise shielding properties that may occur when such intervals or such a gap is formed is less likely to occur. Also, due to the thicknesses of the metal foil 12 and the magnetic layer 13 being within the predetermined ranges, the noise shielding properties are effectively improved, and high flex resistance and high productivity are achieved. In particular, when the communication cable 1 is installed at a portion such as an automobile door where the communication cable 1 is frequently bent, a state in which the shielding foil 10 has high noise shielding properties can be maintained due to the shielding foil 10 having high flex resistance despite the communication cable 1 being repeatedly bent.

### Examples

The following describes examples. Note that the present invention is not limited to these examples. Here, communication cables having a shielding foil and a braid layer in this order on the outer circumference of a core wire and a sheath layer on the outermost circumference as shown in FIG. 2 were envisioned, and noise shielding properties, flex resistance, and productivity were evaluated.

(Samples)

The configurations of the constituent members of the communication cables were as follows.
Core wire: The core wire was formed by providing an insulating layer with a thickness of 0.55 mm made of polyethylene on the outer circumference of a conductor formed by twisting seven copper strands with an outer diameter of 0.18 mm together.
Shielding foil: As constituent materials of the shielding foil, PET with a thickness of 12 μm was used for the substrate, copper was used for the metal foil, and ferrite was used for the magnetic layer. Table 1 shows the types of ferrite. Also, Table 1 shows whether or not the metal foil and the magnetic layer were provided, and the thicknesses thereof. When both the metal foil and the magnetic layer were provided, they were laminated on a surface of the substrate in the order of the magnetic layer and the metal foil as shown in FIG. 1A.
Braid layer: The braid layer was constituted by tinned annealed copper wires. The braid structure had a configuration of 16/5/0.1.
Sheath layer: The sheath layer with a thickness of 0.5 mm containing or free from a magnetic material was provided on the outer circumferential portion. Polypropylene was used as the organic polymer included in the sheath layer. Ferrite powders shown in Table 1 were used as the magnetic materials. The content of the magnetic material was 350 parts by mass with respect to 100 parts by mass of the organic polymer.

(Evaluation of Noise Shielding Properties)

The communication cables were evaluated for noise shielding properties. Here, the amount of emitted noise at 1 GHz was estimated based on the physical properties of the constituent members, such as magnetic permeability. Specifically, the amount of emitted noise was estimated based on Schelkunoff's formula. At this time, the amount of emitted noise was calculated using the given thicknesses of the metal foil and the magnetic layer and the known values of conductivity and magnetic permeability of copper and ferrite. When the estimated amount of emitted noise was −100 dB or less, the noise shielding properties were evaluated as being low (“A”), and when the estimated amount of emitted noise exceeded −100 dB, the noise shielding properties were evaluated as being low (“B”). Note that the amount of emitted noise of −100 dB or less corresponds to the evaluation level “+5” in CISPR25 (standard for “Recommended limits of disturbing wave and methods of measurement for the protection of on-board receivers” by International Special Committee on Radio Interference).

(Evaluation of Flex Resistance)

The communication cables were evaluated for flex resistance. It is conceivable that, when the communication cable is bent, the rate of bending is limited (the bending is limited) due to the flexibility of a copper foil with low strength. Accordingly, the copper foil was kept in a pipe shape and was subjected to a test in which the pipe was bent at a curvature of 0.04, and the number of times it was bent until the copper foil was damaged was counted. When the bending number was 200 or more, the flex resistance was evaluated as being high (“A”), and when the bending number was less than 200, the flex resistance was evaluated as being low (“B”).

(Evaluation of Productivity)

The communication cables were evaluated for productivity from the viewpoint of ease in disposing the shielding foil on the outer circumference of the core wire. In the case of disposing the shielding foil in a longitudinally lapped manner, the productivity significantly depends on the thickness of the shielding foil, and the second moment of area, which is a structural coefficient, largely influences the productivity. Accordingly, regarding the shielding foils, the second moment of area when the shielding foil was disposed in a longitudinally lapped manner was estimated through calculation. When the second moment of area was 1600 mm⁴ or less, the productivity was evaluated as being high (“A”), and when the second moment of area was less than 1600 mm⁴, the productivity was evaluated as being low (“B”).

[Evaluation Results]

Regarding samples A1 to A7 and samples B1 to B8, the configurations of the shielding foil and the sheath layer, and the evaluation results are summarized in Table 1.

TABLE 1

| | | | | | | | Noise shielding properties | | | | |
|---|---|---|---|---|---|---|---|---|---|---|---|
| | | | | | | | Amount of | | | | |
| | Shield foil | | | | | Sheath layer | emitted | | Flex resistance | | |
| | Metal foil | | | Magnetic layer | | Ferrite | noise | | Number of | | |
| Sample | thickness | | Ferrite type | thickness | | material | [dB] | Evaluation | bending | Evaluation | Productivity |
| A1 | 9 | μm | Ni—Zn- | 0.1 | μm | None | −108 | A | 200 | A | A |
| | | | based | | | | | | | | |
| A2 | 9 | μm | Ni—Zn- | 1 | μm | None | −110 | A | 200 | A | A |
| | | | based | | | | | | | | |
| A3 | 9 | μm | Sr-based | 0.1 | μm | Ni—Zn- | −111 | A | 200 | A | A |
| | | | | | | based powder | | | | | |
| A4 | 9 | μm | Sr-based | 1 | μm | Ni—Zn- | −113 | A | 200 | A | A |
| | | | | | | based powder | | | | | |
| A5 | 9 | μm | Mn—Zn- | 1 | μm | Ni—Zn- | −118 | A | 200 | A | A |
| | | | based | | | based powder | | | | | |
| A6 | 5 | μm | Ni—Zn- | 1 | μm | None | −102 | A | 1000 | A | A |
| | | | based | | | | | | | | |
| A7 | 5 | μm | Mn—Zn- | 1 | μm | Ni—Zn- | −110 | A | 1000 | A | A |
| | | | based | | | based powder | | | | | |
| B1 | 5 | μm | None | — | | None | −96 | B | 1000 | A | A |
| B2 | 6 | μm | None | — | | None | −99 | B | 800 | A | A |
| B3 | 15 | μm | None | — | | None | −112 | A | 50 | B | B |
| B4 | 9 | μm | Ni—Zn- | 10 | μm | None | −111 | A | 200 | A | B |
| | | | based | | | | | | | | |
| B5 | None | | None | — | | Ni—Zn- | −8 | B | >1000 | A | A |
| | | | | | | based powder | | | | | |
| B6 | 9 | μm | Sr-based | 10 | μm | Ni—Zn- | −106 | A | 200 | A | B |
| | | | | | | based powder | | | | | |
| B7 | 3 | μm | None | — | | Ni—Zn- | −89 | B | 2000 | A | A |
| | | | | | | based powder | | | | | |
| B8 | 5 | μm | Mn—Zn- | 0.001 | μm | None | −97 | B | 1000 | A | A |
| | | | based | | | | | | | | |

Table 1 shows that the communication cables of samples A1 to A7 having a metal foil with a thickness of 5 μm or more and 12 μm or less and a ferrite layer with a thickness of 0.05 μm or more and 6 μm or less that are integrated with each other on the outer circumference of the core wire had high noise shielding properties, high flex resistance, and high productivity. Regarding samples A1, A2, and A6, the sheath layer did not contain the magnetic material, but the noise shielding properties were substantially the same as those of the other samples in which the sheath layer contains the powder of the magnetic material. That is to say, it can be said that, when the shielding foil is used in the communication cable, it is possible to achieve sufficient noise shielding properties even when the sheath layer does not contain the powder of the magnetic material.

Samples B1, B2, B5, and B7 did not have the magnetic layer included in the shielding foil. In response to this, the noise shielding properties decreased. Regarding samples B5 and B7, the sheath layer contained the magnetic material, but this did not compensate for a decrease in the noise shielding properties caused by the absence of the magnetic layer. Also, regarding sample B8, the shielding foil included the magnetic layer, but the noise shielding properties decreased in response to the magnetic layer having a thickness smaller than 0.05 μm.

Regarding sample B3, although the shielding foil did not include the magnetic layer, high noise shielding properties were achieved due to use of a thick metal foil. However, in response to the metal foil of the shielding foil having a thickness greater than 12 μm, the flex resistance and the productivity of the communication cable decreased. Meanwhile, regarding samples B4 and B6, the thickness of the magnetic layer of the shielding foil exceeded 6 μm. In response to the magnetic layer being excessively thick, the productivity of the communication cables of these samples decreased.

Although embodiments of the present disclosure have been described in detail, the present invention is not limited to the embodiments above, and various modifications can be made without departing from the gist of the present invention.

### LIST OF REFERENCE NUMERALS

1 Communication cable
2 Conductor
3 Insulating layer
4 Core wire
5 Braid layer
6 Sheath layer
10 Shielding foil
11 Substrate
12 Metal foil
13 Magnetic layer

1. A shielding foil comprising:
a metal foil with a thickness of 5 μm or more and 12 μm or less made of a non-magnetic metal; and
a magnetic layer with a thickness of 0.05 μm or more and 6 μm or less made of an oxide magnetic substance,
wherein the metal foil and the magnetic layer are integrally laminated, and
the metal foil and the magnetic layer are in direct contact and joined to each other without being interposed by another constituent layer.

2. The shielding foil according to claim 1,
wherein the metal foil is made of copper or a copper alloy, and
the magnetic layer is made of ferrite.

3. The shielding foil according to claim 1, further comprising
a substrate with a sheet shape containing an organic polymer,
wherein the metal foil and the magnetic layer are formed on a surface of the substrate.

4. The shielding foil according to claim 1,
wherein the magnetic layer has a thickness of 1 μm or less.

5. The shielding foil according to claim 1,
wherein the magnetic layer is obtained by oxidizing a metal layer formed through vapor deposition.

6. A communication cable comprising:
a conductor;
an insulating layer covering an outer circumference of the conductor; and
the shielding foil according to claim 1 that surrounds an outside of the insulating layer.

7. The communication cable according to claim 6, further comprising
a sheath layer that covers an outside of the insulating layer and contains an organic polymer and a powdery magnetic material.

8. The communication cable according to claim 6, further comprising
a metal braid on an outside or an inside of the shielding foil.

9. The communication cable according to claim 6,
wherein the communication cable is formed as a coaxial cable.

10. A shielding foil manufacturing method for manufacturing the shielding foil according to claim 1, the method comprising
a step of forming the magnetic layer by forming a metal layer on a surface of the metal foil through vapor deposition and oxidizing the metal layer.
